(19) United States
(12) Patent Application Publication
(10) Pub. No.: US 2026/0173675 A1
(43) Pub. Date: Jun. 18, 2026

(54) DISPLAY DEVICE, ELECTRONIC DEVICE, OPTICAL DEVICE AND METHOD FOR FABRICATING DISPLAY DEVICE

(71) Applicant: Samsung Display Co., Ltd., Yongin-si (KR)

(72) Inventors: Sin Chul KANG, Yongin-si (KR); Ju Won YOON, Yongin-si (KR); Jae Been LEE, Yongin-si (KR); Ye Hwan CHOI, Yongin-si (KR)

(21) Appl. No.: 19/335,815

(22) Filed: Sep. 22, 2025

(30) Foreign Application Priority Data
Dec. 16, 2024 (KR) 10-2024-0186844

(51) Int. Cl. H10K 59/127; H10K 59/121; H10K 59/122; H10K 59/131; H10K 59/80

(52) U.S. Cl. CPC H10K 59/1275; H10K 59/1213; H10K 59/122; H10K 59/131; H10K 59/80515

(57) ABSTRACT

A display device includes: a driving module comprising a first substrate having pixel circuits; and a display module on the driving module, wherein the display module includes: a second substrate; a plurality of light emitting elements on a first surface of the second substrate and respectively connected to the plurality of pixel circuits; a plurality of vias penetrating the second substrate; and a plurality of anode connection electrodes respectively in the plurality of vias and connecting the plurality of pixel circuits to the plurality of light emitting elements, the via including a hole and a groove connected to each other, the hole penetrating the second substrate, the groove is on a second surface of the second substrate so as to be between the second substrate and the driving module, and the plurality of vias have grooves with smaller lengths and are closer to a center of the second substrate.

### CROSS-REFERENCE TO RELATED APPLICATION

The present application claims priority to and the benefit of Korean Patent Application No. 10-2024-0186844, filed on Dec. 16, 2024, in the Korean Intellectual Property Office, the entire disclosure of which is incorporated herein by reference.

### BACKGROUND

### 1. Field

Aspects of some embodiments of the present disclosure relate to a display device.

### 2. Description of the Related Art

Because an organic light emitting diode (OLED) display is self-emissive and generally does not require a separate light source unlike a liquid crystal display, its thickness and weight may be relatively reduced. In addition, an OLED display has garnered attention as a next-generation display for TVs, monitors, and portable electronic devices due to its superior characteristics such as low power consumption, high luminance, and high response speed.

The above information disclosed in this Background section is only for enhancement of understanding of the background and therefore the information discussed in this Background section does not necessarily constitute prior art.

### SUMMARY

Aspects of some embodiments of the present disclosure relate to a display device, and for example, to a display device, an electronic device, an optical device, and a method for fabricating the display device, which are capable of increasing light efficiency and relatively reducing resistance of a cathode electrode.

Aspects of some embodiments of the present disclosure include a display device, an electronic device, an optical device, and a method for fabricating the display device, which are capable of increasing light efficiency and relatively reducing resistance of a cathode electrode.

According to some embodiments of the present disclosure, a display device includes: a driving module (M1) comprising a first substrate (SUB1) and a plurality of pixel circuits (PC) on the first substrate; and a display module (M2) located on the driving module, wherein the display module comprises: a second substrate (SUB2); a plurality of light emitting elements (ED) arranged on a first surface (21) of the second substrate and respectively connected to the plurality of pixel circuits; a plurality of vias (TGV) penetrating the second substrate; and a plurality of anode connection electrodes (ACE) respectively located in the plurality of vias and respectively connecting the plurality of pixel circuits to the plurality of light emitting elements, wherein the via comprises a hole (TH) and a groove (GR) connected to each other, the hole penetrates the second substrate, the groove is arranged on a second surface (22) of the second substrate so as to be located between the second substrate and the driving module, and the plurality of vias have grooves with smaller lengths as they are closer to a center of the second substrate.

According to some embodiments of the present disclosure, an electronic device includes a display device providing a screen, wherein the display device comprises: a driving module (M1) comprising a first substrate (SUB1) and a plurality of pixel circuits (PC) on the first substrate; and a display module (M2) located on the driving module, wherein the display module comprises: a second substrate (SUB2); a plurality of light emitting elements (ED) arranged on a first surface (21) of the second substrate and respectively connected to the plurality of pixel circuits; a plurality of vias (TGV) penetrating the second substrate; and a plurality of anode connection electrodes (ACE) respectively located in the plurality of vias and respectively connecting the plurality of pixel circuits to the plurality of light emitting elements, wherein the via comprises a hole (TH) and a groove (GR) connected to each other, the hole penetrates the second substrate, the groove is arranged on a second surface (22) of the second substrate so as to be located between the second substrate and the driving module, and the plurality of vias have grooves with smaller lengths as they are closer to a center of the second substrate.

According to some embodiments of the present disclosure, an optical device includes: a display device; and an optical path changing member on the display device, wherein the display device comprises: a driving module (M1) comprising a first substrate (SUB1) and a plurality of pixel circuits (PC) on the first substrate; and a display module (M2) located on the driving module, wherein the display module comprises: a second substrate (SUB2); a plurality of light emitting elements (ED) arranged on a first surface (21) of the second substrate and respectively connected to the plurality of pixel circuits; a plurality of vias (TGV) penetrating the second substrate; and a plurality of anode connection electrodes (ACE) respectively located in the plurality of vias and respectively connecting the plurality of pixel circuits to the plurality of light emitting elements, wherein the via comprises a hole (TH) and a groove (GR) connected to each other, the hole penetrates the second substrate, the groove is arranged on a second surface (22) of the second substrate so as to be located between the second substrate and the driving module, and the plurality of vias have grooves with smaller lengths as they are closer to a center of the second substrate.

According to some embodiments of the present disclosure, in a method for fabricating a display device, the method includes: preparing a substrate of a display module; irradiating a first laser beam onto a second surface of the substrate so as to penetrate a first surface and the second surface of the substrate; irradiating a second laser beam onto the first surface so as not to penetrate the substrate; forming a plurality of vias having a hole in a region irradiated with the first laser beam and a groove in a region irradiated with the second laser beam by etching the substrate irradiated with the first laser beam and the second laser beam; forming a metal layer on the first surface, the second surface, and the plurality of vias of the substrate; forming a plurality of anode connection electrodes in the plurality of vias, respectively, by removing the metal layer on the first surface and the second surface of the substrate; forming a plurality of anode electrodes, which are respectively connected to the plurality of anode connection electrodes, on the first surface of the substrate; forming a pixel defining film on the anode electrodes; forming an interlayer insulating layer on the second surface of the substrate; forming a plurality of interlayer connection electrodes, which are respectively connected to the plurality of anode connection electrodes through contact holes penetrating the interlayer insulating layer; and connecting a plurality of pixel circuits of a driving module to the plurality of interlayer connection electrodes of the display module, respectively.

According to some embodiments of the present disclosure, in the display device, the electronic device, the optical device, and the method for fabricating the display device, it may be possible to increase light efficiency and relatively reduce resistance of a cathode electrode.

For example, according to some embodiments, a pixel circuit and a light emitting element may be located on different substrates. Accordingly, the anode electrode of the light emitting element may include a material containing silver (Ag) with high reflectivity, and a pixel defining film may include a material containing an organic material. As a result, the reflectivity of the anode electrode may increase, thereby relatively improving light efficiency, and the taper angle of the pixel defining film may be relatively reduced. Consequently, the step coverage of a cathode electrode located on the pixel defining film may be relatively improved, thereby relatively reducing the resistance of the cathode electrode.

The characteristics of embodiments according to the present disclosure are not limited to the above-described characteristics and other characteristics which are not described herein will become apparent to those skilled in the art from the following description.

### BRIEF DESCRIPTION OF THE DRAWINGS

The above and other aspects and characteristics of some embodiments of the present disclosure will become more apparent by describing in more detail aspects of some embodiments thereof with reference to the attached drawings, in which:

FIG. 1 is an exploded perspective view showing a display device according to some embodiments;

FIG. 2 is a block diagram showing the display device according to some embodiments;

FIG. 3 is an equivalent circuit diagram of a pixel according to some embodiments;

FIG. 4 is a plan view of the display device shown in FIG. 1;

FIG. 5 is a view of FIG. 4 with a pixel circuit and an interlayer connection electrode removed;

FIG. 6 is a view of FIG. 4 with a light emitting element removed;

FIG. 7 is a cross-sectional view taken along the line I-I′ of FIG. 4;

FIG. 8 is a plan view of a second substrate according to some embodiments;

FIG. 9 is a rear view of FIG. 8;

FIG. 10 is an enlarged view of any one of vias of FIG. 9;

FIGS. 11, 12, 13, 14, 15, 16, 17, 18, 19, 20, and 21 are process cross-sectional views illustrating a method for fabricating the display device according to some embodiments;

FIG. 22 is a perspective view showing an electronic device to which the display device according to some embodiments is applied;

FIG. 23 is a perspective view illustrating a head mounted display according to some embodiments; and

FIG. 24 is an exploded perspective view illustrating an example of the head mounted display of FIG. 23.

FIG. 25 is a block diagram of an electronic device according to some embodiments.

FIGS. 26, 27 and 28 are schematic diagrams of electronic devices according to some embodiments.

### DETAILED DESCRIPTION

Aspects of some embodiments of the present disclosure will now be described more fully hereinafter with reference to the accompanying drawings, in which aspects of some embodiments of the invention are shown. This invention may, however, be embodied in different forms and should not be construed as limited to the embodiments set forth herein. Rather, these embodiments are provided so that this disclosure will be more thorough and more complete, and will more fully convey the scope of embodiments according to the present disclosure to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or totally. As will be clearly appreciated by those skilled in the art, technically various interactions and operations are possible. Various embodiments can be practiced individually or in combination.

Hereinafter, aspects of some embodiments will be described in more detail with reference to the accompanying drawings.

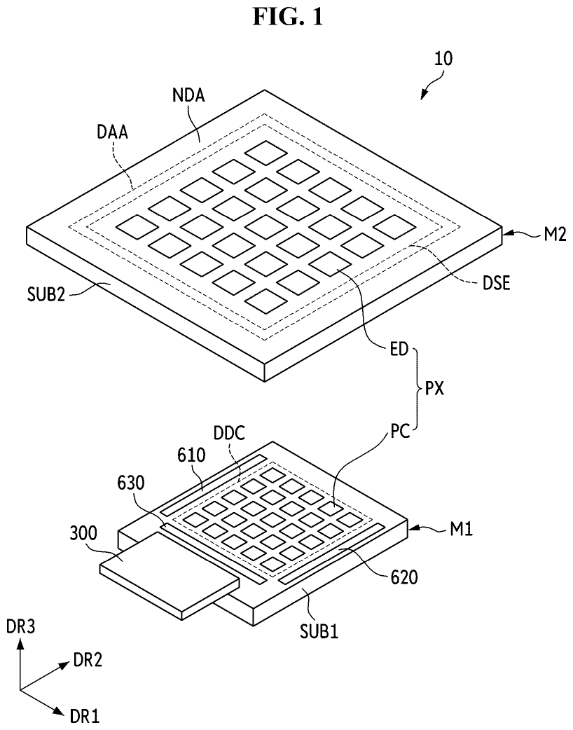

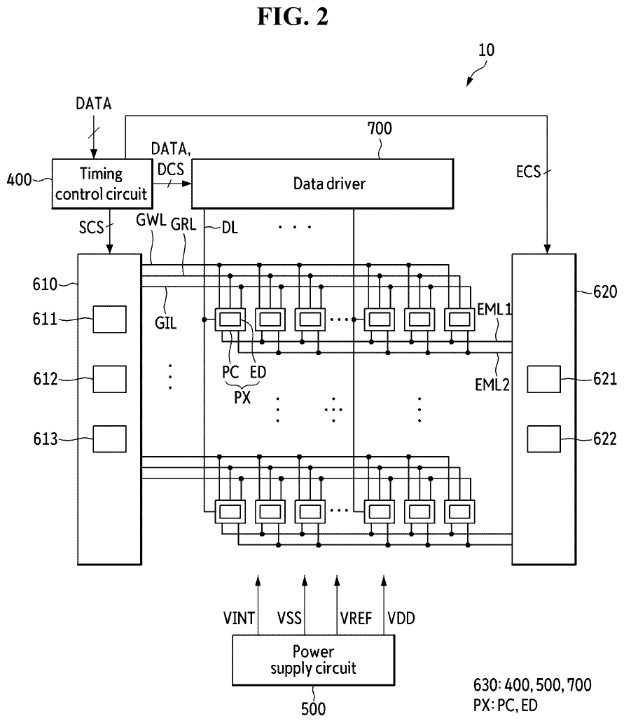

FIG. 1 is an exploded perspective view showing a display device 10 according to some embodiments. FIG. 2 is a block diagram showing the display device 10 according to some embodiments.

Referring to FIG. 1, the display device 10 according to some embodiments is a device configured to display moving images (e.g., video images) or still images (e.g., static images). The display device 10 according to some embodiments may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like. For example, the display device 10 according to some embodiments may be applied as a display unit of a television, a laptop, a monitor, a billboard, or an Internet-of-Things (IoT) terminal. Alternatively, the display device 10 according to some embodiments may be applied to a smart watch, a watch phone, a head mounted display (HMD) for implementing virtual reality and augmented reality, and the like.

The display device 10 according to some embodiments may include a plurality of pixels PX for displaying an image. The plurality of pixels PX may include a first pixel, a second pixel, and a third pixel that provide light of different colors (or different wavelengths). The pixel PX may include a pixel circuit PC and a light emitting element ED connected to each other.

The display device 10 according to some embodiments may include a driving module M1 and a display module M2. The driving module M1 and the display module M2 may be connected to each other.

The driving module M1 may include a first substrate SUB1, a first driving circuit 610, a second driving circuit 620, a third driving circuit 630, a display driving circuit DDC, and a circuit board 300.

The first substrate SUB1 may be a wafer substrate (e.g., a semiconductor substrate).

The first driving circuit 610, the second driving circuit 620, the third driving circuit 630, and the display driving circuit DDC may be located on the first substrate SUB1.

The first driving circuit 610, the second driving circuit 620, and the third driving circuit 630 may provide various signals (e.g., driving signals and data) required for the display driving circuit DDC and the display module M2.

The display driving circuit DDC may drive a display element DSE of the display module M2. The display driving circuit DDC may include the plurality of pixel circuits PC.

The circuit board 300 may be connected to one side of the first substrate SUB1. The circuit board 300 may be electrically connected to a plurality of pads of the first substrate SUB1 by using a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, one end of the circuit board 300 may be located on the rear surface of the first substrate SUB1. One end of the circuit board 300 may be opposite to the other end of the circuit board 300 connected to the plurality of pads of the first substrate SUB1 by using a conductive adhesive member.

The display module M2 may display images. The display module M2 may be located on the driving module M1.

The display module M2 may include a second substrate SUB2 and the display element DSE.

The second substrate SUB2 may be a glass substrate or a polyimide substrate.

The display element DSE may be located on the second substrate SUB2. For example, the display element DSE may be located in a display area DAA of the display module M2. A non-display area NDA of the display module M2 may surround (e.g., in a periphery or outside a footprint of) the display area DAA of the display module M2. The display element DSE may include the plurality of light emitting elements ED.

Hereinafter, further detailed description of the above-described display device 10 will be provided with reference to FIG. 2.

FIG. 2 is a block diagram of the display device 10 according to some embodiments.

The pixel PX may include the pixel circuit PC and the light emitting element ED connected to the pixel circuit PC. A driving current generated by the pixel circuit PC may be supplied to the light emitting element ED.

The plurality of pixel circuits PC, a plurality of scan lines SL, a plurality of emission control lines EML, and a plurality of data lines DL may be arranged on the first substrate SUB1.

The plurality of light emitting elements ED may be arranged on the second substrate SUB2.

The plurality of pixel circuits PC may be arranged in a matrix form in a first direction DR1 and a second direction DR2. The plurality of scan lines SL and the plurality of emission control lines EML may extend in the first direction DR1, while being arranged in the second direction DR2. The plurality of data lines DL may extend in the second direction DR2, while being arranged in the first direction DR1.

The plurality of scan lines SL include a plurality of write scan lines GWL, a plurality of reset scan lines GRL, and a plurality of initialization scan lines GIL. The plurality of emission control lines EML may include a plurality of first emission control lines EL1 and a plurality of second emission control lines EL2.

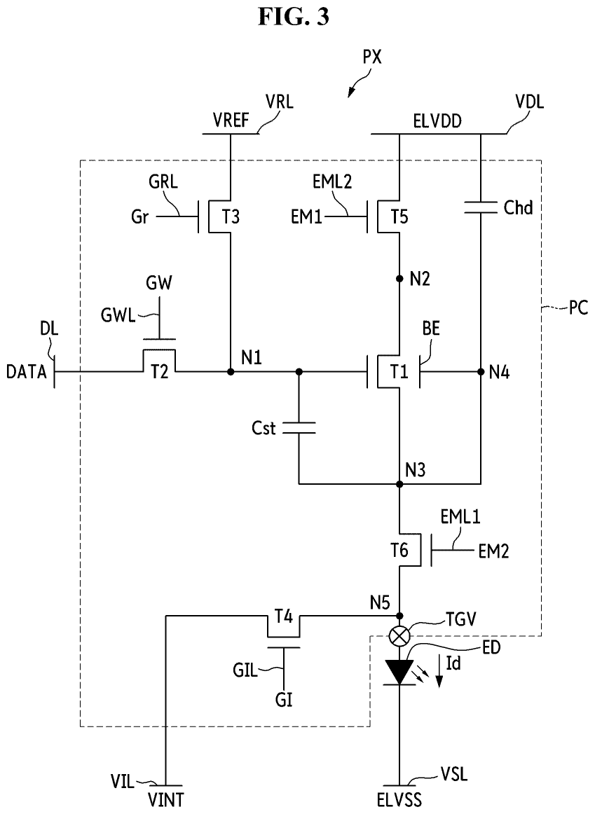

The pixel circuit PC may include a plurality of pixel transistors (e.g., T1, T2, T3, T4, T5, and T6 in FIG. 3), and the plurality of pixel transistors may be formed through a semiconductor process and may be arranged on the first substrate SUB1. For example, the plurality of pixel transistors may include a metal oxide semiconductor (MOS). For example, the pixel transistors may be formed as p-type MOS transistors or n-type MOS transistors.

Each of the plurality of pixel circuits PC may be connected to any one of the plurality of write scan lines GWL, any one of the plurality of reset scan lines GRL, any one of the plurality of initialization scan lines GIL, any one of the plurality of first emission control lines EL1, any one of the plurality of second emission control lines EL2, and any one of the plurality of data lines DL. Each of the plurality of pixel circuits PC may receive the data voltage of the data line DL according to the write scan signal of the write scan line GWL, and may cause the light emitting element ED to emit light according to the data voltage.

The first driving circuit 610 may include a plurality of scan transistors. The plurality of scan transistors may be formed through a semiconductor process and may be formed on the first substrate SUB1. For example, the plurality of scan transistors may be formed as p-type MOS transistors or n-type MOS transistors.

The first driving circuit 610 may include a write scan signal output unit 611, a reset scan signal output unit 612, and an initialization scan signal output unit 613. Each of the write scan signal output unit 611, the reset scan signal output unit 612, and the initialization scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The reset scan signal output unit 612 may generate reset scan signals in response to the scan timing control signal SCS and sequentially output them to the reset scan lines GRL. The initialization scan signal output unit 613 may generate initialization scan signals in response to the scan timing control signal SCS and sequentially output them to the initialization scan lines GIL.

The second driving circuit 620 may include a plurality of light emitting transistors. The plurality of light emitting transistors may be formed through a semiconductor process and may be formed on the first substrate SUB1. For example, the plurality of light emitting transistors may be formed as p-type MOS transistors or n-type MOS transistors.

The second driving circuit 620 may include a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The third driving circuit 630 may include a data driver 700, a timing control circuit 400, and a power supply circuit 500.

The data driver 700 may receive digital video data DATA and a data timing control signal DCS from the timing control circuit 400. The data driver 700 converts the digital video data DATA into analog data voltages according to the data timing control signal DCS and outputs the analog data voltages to data lines DL. In this case, the pixels PX may be selected by the write scan signal of the first driving circuit 610, and data voltages may be supplied to the selected pixels PX.

The timing control circuit 400 may receive digital video data and timing signals inputted from the outside. The timing control circuit 400 may generate the scan timing control signal SCS, the emission timing control signal ECS, and a data timing control signal DCS in response to the timing signals. The timing control circuit 400 may output the scan timing control signal SCS to the first driving circuit 610, and output the emission timing control signal ECS to the second driving circuit 620. The timing control circuit 400 may output the digital video data and the data timing control signal DCS to the data driver 700.

FIG. 3 is an equivalent circuit diagram of the pixel PX according to some embodiments. For example, FIG. 3 may be an equivalent circuit diagram for the pixel PX of FIGS. 1 and 2. Although FIG. 3 illustrates various components in a pixel PX according to some embodiments, embodiments according to the present disclosure are not limited thereto, and according to various embodiments, the pixel PX may include additional components or fewer components without departing from the spirit and scope of embodiments according to the present disclosure.

As shown in FIG. 3, the pixel PX may include the light emitting element ED and the pixel circuit PC connected to the light emitting element ED. The light emitting element ED is a light source of the pixel PX, and it may be, for example, an organic light emitting diode, but is not limited thereto.

The pixel circuit PC may include pixel transistors (e.g., the first to sixth transistors T1 to T6), a first capacitor Cst, and a second capacitor Chd.

The pixel circuit PC may supply a driving current Id to the light emitting element ED in response to scan signals, emission control signals, and data signals supplied from the first driving circuit 610, the second driving circuit 620, and the data driver 700, respectively. For example, the pixel circuit PC may supply the driving current Id to the light emitting element ED in response to scan signals GW, GR, and GI supplied from the first driving circuit 610 through the respective scan lines GWL, GRL, and GIL, emission control signals EM1 and EM2 supplied from the second driving circuit 620 through the respective emission control lines EML1 and EML2, and a data signal DATA supplied from the data driver 700 through the data line DL.

The first transistor T1 may be a driving transistor of the pixel PX whose magnitude of a drain-source current (e.g., the driving current Id) is determined depending on a gate-source voltage. The second, third, fourth, fifth, and sixth transistors T2, T3, T4, T5, and T6 may be switching transistors that are turned on or off depending on respective gate-source voltages.

The pixel circuit PC may be connected to the write scan line GWL that transmits a write scan signal GW (e.g., a scan signal), the initialization scan line GIL that transmits an initialization scan signal GI, the reset scan line GRL that transmits a reset scan signal Gr, the first emission control line EML1 that transmits a first emission control signal EM1, the second emission control line EML2 that transmits a second emission control signal EM2, and the data line DL that transmits the data signal DATA. In addition, the pixel circuit PC may be connected to a driving power line VDL that transmits a driving voltage ELVDD and a common power line VSL that transmits a common voltage ELVSS. According to some embodiments, the pixel circuit PC may be further connected to an initialization power line VIL that transmits the initialization voltage VINT and a reference power line VRL that transmits the reference voltage VREF.

The first transistor T1 may include a gate electrode connected to a first node N1, a drain electrode connected to a second node N2, and a source electrode connected to a third node N3. The drain electrode of the first transistor T1 may be connected to the driving power line VDL via the fifth transistor T5, and the source electrode thereof may be connected to the light emitting element ED via the sixth transistor T6. The first transistor T1 may control the magnitude (e.g., current amount) of the driving current Id flowing to the light emitting element ED to correspond to the data signal DATA transmitted to the first node N1. According to some embodiments, a body electrode BE of the first transistor T1 may be connected to a fourth node N4.

The second transistor T2 may include a gate electrode connected to the write scan line GWL, a drain electrode connected to the data line DL, and a source electrode connected to the first node N1. The second transistor T2 may be turned on by the write scan signal GW transmitted through the write scan line GWL to connect the data line DL with the first node N1. Accordingly, the data signal DATA transmitted through the data line DL may be sent to the first node N1.

The third transistor T3 may include a gate electrode connected to the reset scan line GRL, a source electrode connected to the reference power line VRL, and a drain electrode connected to the first node N1. The third transistor T3 may be turned on by the reset scan signal GR transmitted through the reset scan line GRL and transmit the reference voltage VREF transmitted through the reference power line VRL to the first node N1.

The fourth transistor T4 may include a gate electrode connected to the initialization scan line GIL, a drain electrode connected to a fifth node N5, and a source electrode connected to the initialization power line VIL. The fourth transistor T4 may be turned on by the initialization scan signal GI transmitted through the initialization scan line GIL and transmit the initialization voltage VINT transmitted through the initialization power line VIL to the fifth node N5.

The fifth transistor T5 may include a gate electrode connected to the first emission control line EML1, a drain electrode connected to the driving power line VDL, and a source electrode connected to the second node N2. The fifth transistor T5 may be turned on by the first emission control signal EM1 transmitted through the first emission control line EML1 to control the emission timing of the pixel PX.

The sixth transistor T6 may include a gate electrode connected to the second emission control line EML2, a drain electrode connected to the third node N3, and a source electrode connected to the fifth node N5. The sixth transistor T6 may be turned on by the second emission control signal EM2 transmitted through the second emission control line EML2 to control the emission timing of the pixel PX.

The first capacitor Cst may be connected between the first node N1 and the third node N3. The first capacitor Cst is a storage capacitor of the pixel PX, and may store therein a threshold voltage of the first transistor T1 and a voltage corresponding to the data signal DATA (e.g., a data voltage).

The second capacitor Chd may be connected between the driving power line VDL and the fourth node N4. According to some embodiments, the capacitance of the second capacitor Chd may be less than that of the first capacitor Cst.

The light emitting element ED may be connected between the fifth node N5 and the common power line VSL. For example, the light emitting element ED may include an anode electrode AE connected to the fifth node N5, a cathode electrode CE facing the anode electrode AE and connected to the common power line VSL, and a light emitting layer LE interposed between the anode electrode AE and the cathode electrode CE. According to some embodiments, the anode electrode AE of the light emitting element ED may be an individual electrode individually provided in each pixel PX, and the anode electrode AE of the light emitting element ED may be a common electrode shared by the plurality of pixels PX. The light emitting element ED may emit light with a luminance corresponding to the driving current Id during a time period in which the driving current Id is supplied from the pixel circuit PC. The light emitting element ED may be connected to the pixel circuit PC through a via TGV penetrating the second substrate SUB2. For example, the anode electrode AE of the light emitting element ED may be connected to the fifth node N5 of the pixel circuit PC through the via TGV of the second substrate SUB2.

Each of the first to sixth transistors T1 to T6 may be a metal-oxide-semiconductor field effect transistor (MOSFET). For example, each of the first to sixth transistors T1 to T6 may be a p-type MOSFET, but the present disclosure is not limited thereto. Each of the first to sixth transistors T1 to T6 may be an n-type MOSFET.

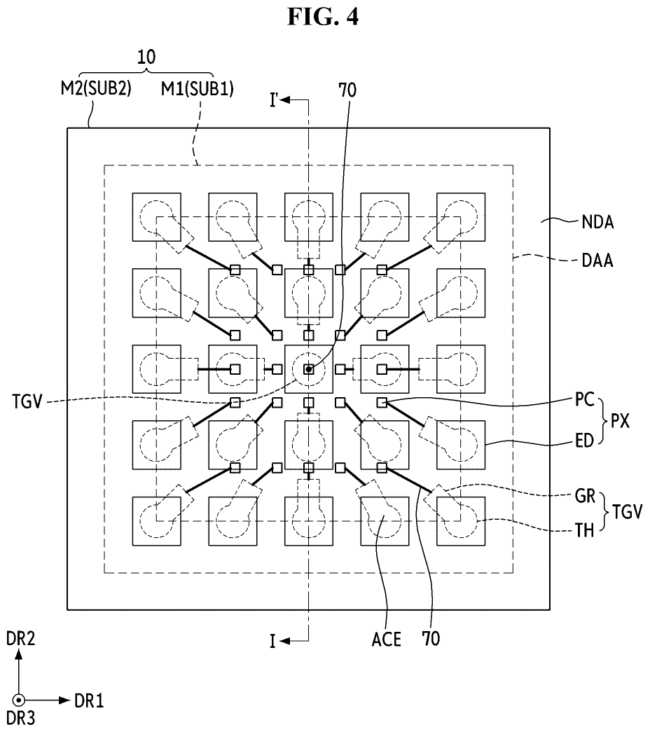

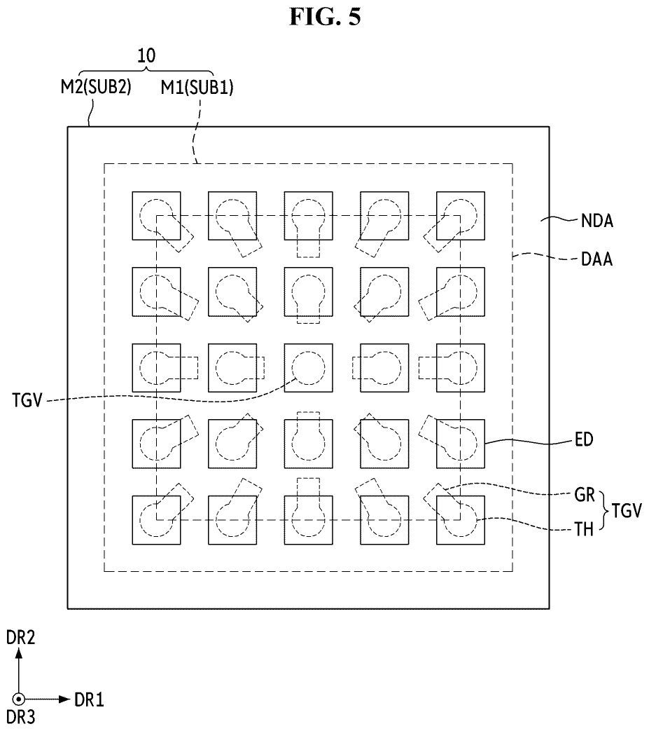

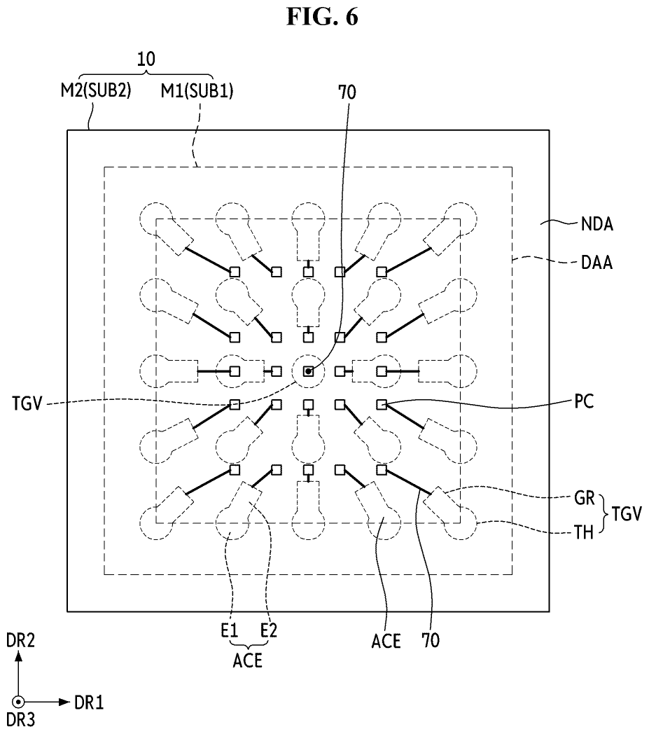

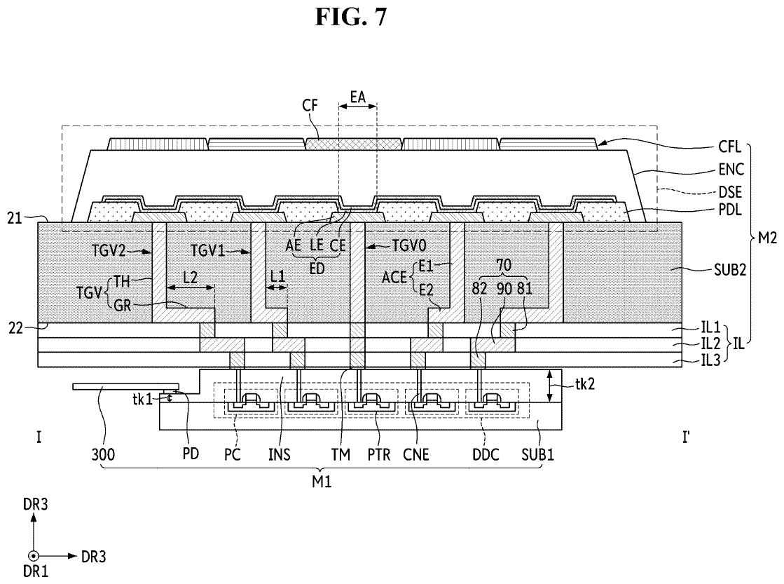

FIG. 4 is a plan view of the display device 10 shown in FIG. 1. FIG. 5 is a view of FIG. 4 with the pixel circuit PC and an interlayer connection electrode 70 removed. FIG. 6 is a view of FIG. 4 with the light emitting element ED removed. FIG. 7 is a cross-sectional view taken along line I-I′ of FIG. 4.

As shown in FIG. 7, the driving module M1 may include the display driving circuit DDC located on the first substrate SUB1, an insulating layer INS located on the display driving circuit DDC, a plurality of terminals TM on the insulating layer INS, and the circuit board 300 connected to a pad PD of the first substrate SUB1.

The display driving circuit DDC may include the plurality of pixel circuits PC.

Each of the pixel circuits PC may include a pixel transistor PTR. The pixel transistor PTR in FIG. 7 may be, for example, the first transistor T1 in FIG. 3 described above.

The insulating layer INS may be located on the pixel transistors PTR. The insulating layer INS may have different thicknesses. For example, the insulating layer INS may have a smaller thickness (tk1<tk2) in a region overlapping the plurality of pads PD than in a region overlapping the plurality of terminals TM. Accordingly, a space in which the circuit board 300 and the pads PD can be connected to each other may be secured between the driving module M1 and the display module M2.

The plurality of terminals TM may be arranged on the insulating layer INS. For example, the plurality of terminals TM may be arranged on the insulating layer INS to overlap the display driving circuit DDC. The plurality of terminals TM may be respectively connected to the plurality of pixel transistors PTR through a plurality of contact holes of the insulating layer INS. For example, the plurality of terminals TM may be respectively connected to the plurality of drain electrodes of the plurality of pixel transistors PTR through intermediate connection electrodes CNE located in the plurality of contact holes of the insulating layer INS.

The light emitting element ED may be located on the top surface of the second substrate SUB2. The light emitting element ED may include the anode electrode AE, the light emitting layer LE, and the cathode electrode CE. The emission area EA represents a region where the anode electrode AE, the light emitting layer LE and the cathode electrode CE are stacked sequentially and holes from the anode electrode AE and electrons from the cathode electrode CE are coupled to each other in the light emitting layer LE to emit light.

In a top emission structure, in which light is emitted toward the cathode electrode CE when viewed with respect to the light emitting layer LE, the anode electrode AE may be formed to have a stacked structure (ITO/Al/ITO) of silver and ITO or a stacked structure (ITO/APC/ITO) of an APC alloy and ITO to increase reflectivity. The APC alloy may be an alloy of silver (Ag), palladium (Pd) and copper (Cu).

A pixel defining film PDL may serve to define the emission areas EA of the pixels PX. To this end, the pixel defining film PDL may be located to expose a partial area of the anode electrode AE on a top surface 21 of the second substrate SUB2. The pixel defining film PDL may cover an edge of the anode electrode AE. The pixel defining film PDL may include an organic film such as acryl resin, epoxy resin, phenolic resin, polyamide resin, polyimide resin and the like.

The light emitting layer LE may be formed on the anode electrode AE and the pixel defining film PDL. The light emitting layer LE may include an organic material to emit light in a selected color. For example, the light emitting layer LE may include a hole transporting layer, an organic material layer, and an electron transporting layer. The organic material layer may include a host and a dopant. The organic material layer may include a material that emits selected light, and may be formed using a phosphorescent material or a fluorescent material. The light emitting layer may have a tandem structure.

The cathode electrode CE may be located on the light emitting layer LE. The cathode electrode CE may be located to cover the light emitting layer LE. In the top emission structure, the cathode electrode CE may include a transparent conductive material (TCO) such as ITO or IZO capable of transmitting light or a semi-transmissive conductive material such as magnesium (Mg), silver (Ag), or an alloy of magnesium (Mg) and silver (Ag). When the cathode electrode CE includes a semi-transmissive conductive material, the light output efficiency can be increased due to a micro-cavity effect.

An encapsulation layer ENC may be located on the light emitting elements ED. The encapsulation layer ENC may include at least one inorganic film to prevent or relatively reduce instances of contaminants, such as oxygen or moisture permeating into the light emitting element ED. In addition, the encapsulation layer ENC may include at least one organic film to protect the light emitting element ED from foreign substances such as dust. For example, the encapsulation layer ENC may include a first inorganic film, an organic film, and a second inorganic film. The inorganic film of the encapsulation layer ENC may be formed as a multilayer in which one or more inorganic films of a silicon nitride layer, a silicon oxynitride layer, a silicon oxide layer, a titanium oxide layer and an aluminum oxide layer are alternately stacked. The organic film TFE2 of the encapsulation layer ENC may be an organic film such as acryl resin, epoxy resin, phenolic resin, polyamide resin, polyimide resin or the like.

The color filter layer CFL may be located on the encapsulation layer ENC. The color filter layer CFL may include a plurality of color filters CF arranged to respectively correspond to different emission areas. The plurality of color filters CF may include a first color filter, a second color filter, and a third color filter capable of selectively transmitting light of different colors.

As shown in FIG. 7, the display module M2 may further include an interlayer insulating layer IL. The interlayer insulating layer IL may be located on the bottom surface of the second substrate SUB2. For example, the interlayer insulating layer IL may be located between the driving module M1 and the second substrate SUB2.

The interlayer insulating layer IL may be formed as a multilayer in which one or more inorganic films of a silicon nitride layer, a silicon oxynitride layer, a silicon oxide layer, a titanium oxide layer and an aluminum oxide layer are alternately stacked. For example, the interlayer insulating layer IL may include a first interlayer insulating layer IL1, a second interlayer insulating layer IL2, and a third interlayer insulating layer IL3.

The first interlayer insulating layer IL1 may be located on the bottom surface of the second substrate SUB2. For example, the first interlayer insulating layer IL1 may be located between the bottom surface of the second substrate SUB2 and the second interlayer insulating layer IL2.

The second interlayer insulating layer IL2 may be located on the first interlayer insulating layer IL1. For example, the second interlayer insulating layer IL2 may be located between the first interlayer insulating layer IL1 and the third interlayer insulating layer IL3.

The third interlayer insulating layer IL3 may be located on the second interlayer insulating layer IL2. For example, the third interlayer insulating layer IL3 may be located between the second interlayer insulating layer IL2 and the terminals TM of the driving module M1.

A plurality of anode connection electrodes ACE may be respectively located in the plurality of vias TGV of the second substrate SUB2,

The plurality of anode connection electrodes ACE may be respectively connected to the plurality of anode electrodes AE.

The via TGV may include a hole TH and a groove GR connected to each other.

The hole TH may penetrate the second substrate SUB2. For example, the top surface 21 and a bottom surface 22 of the second substrate SUB2 may be penetrated by the hole TH. In a plan view as shown in FIGS. 4 to 6, the hole TH may have a circular shape. However, the shape of the hole TH is not limited thereto, and may be variously modified.

The groove GR may communicate with the hole TH. The groove GR may be formed on the bottom surface 22 of the second substrate SUB2. The groove GR may be formed in a recessed shape on the bottom surface 22 of the second substrate SUB2. For example, the groove GR may be located on the bottom surface 22 of the second substrate SUB2 in a recessed shape in a direction (e.g., a third direction DR3) toward the top surface of the second substrate SUB2 from the bottom surface 22 of the second substrate SUB2. In a plan view as shown in FIGS. 4 to 6, the groove GR may have a quadrilateral shape. However, the shape of the groove GR is not limited thereto, and may be variously modified.

As shown in FIGS. 4 to 7, the vias TGV may have the grooves GR with different lengths. For example, the vias TGV may have the grooves GR with smaller lengths (L1<L2) as they are closer to the center of the second substrate SUB2. In other words, the vias TGV may have the grooves GR with larger lengths as they are closer to the edge of the second substrate SUB2. For example, as shown in FIG. 7, when the via TGV located at the center of the second substrate SUB2 is defined as a central via TGV0, the via TGV located at one edge of the second substrate SUB2 is defined as a second via TGV2, and the via TGV between the central via TGV0 and the second via TGV2 is defined as a first via TGV1, the length L1 of the groove GR of the first via TGV1 may be greater than the length of the groove GR of the central via TGV0 and smaller than the length L2 of the groove GR of the second via TGV2. According to some embodiments, the central via TGV0 may include the hole TH and may not include the groove GR. In other words, the length of the groove GR of the central via TGV0 may be zero.

As shown in FIGS. 4 to 7, the groove GR of each via TGV may extend toward the center of the second substrate SUB2. For example, the groove GR of the first via TGV1 may extend in a direction from the hole TH of the first via TGV1 toward the central via TGV0, and the groove GR of the second via TGV2 may extend in a direction from the hole TH of the second via TGV2 toward the central via TGV0.

The anode connection electrode ACE in each via TGV may include a first connection electrode E1 and a second connection electrode E2. The first connection electrode E1 and the second connection electrode E2 may be connected to each other. For example, the first connection electrode E1 and the second connection electrode E2 may be integrally formed.

The first connection electrode E1 of the anode connection electrode ACE may be located in the hole TH of the via TGV, and the second connection electrode E2 of the anode connection electrode ACE may be located in the groove GR of the via TGV.

As shown in FIGS. 4 to 7, the anode connection electrodes ACE may have the second connection electrodes E2 with different lengths. For example, the anode connection electrodes ACE may have the second connection electrodes E2 with smaller lengths (e.g., L1<L2) as they are closer to the center of the second substrate SUB2. In other words, the anode connection electrodes ACE may have the second connection electrodes E2 with larger lengths as they are closer to the edge of the second substrate SUB2. For example, as shown in FIG. 7, when the anode connection electrode ACE located in the central via TGV0 is defined as a central anode connection electrode, the anode connection electrode ACE located in the first via TGV1 is defined as a first anode connection electrode, and the anode connection electrode ACE located in the second via TGV2 is defined as a second anode connection electrode, the length of the second connection electrode E2 of the first anode connection electrode is greater than the length of the second connection electrode E2 of the central anode connection electrode and smaller than the length of the second connection electrode E2 of the second anode connection electrode. According to some embodiments, the central anode connection electrode may include the first connection electrode E1 and may not include the second connection electrode E2. In other words, the length of the second connection electrode E2 of the central anode connection electrode may be zero.

As shown in FIGS. 4 to 7, the second connection electrode E2 of each anode connection electrode ACE may extend toward the center of the second substrate SUB2. For example, the second connection electrode E2 of the first anode connection electrode may extend in a direction from the first connection electrode E1 of the first anode connection electrode toward the central anode connection electrode, and the second connection electrode E2 of the second anode connection electrode may extend in a direction from the first connection electrode E1 of the second anode connection electrode toward the central anode connection electrode.

One side of the second connection electrode E2 of the anode connection electrode ACE may be connected to the first connection electrode E1. In a plan view, the anode connection electrode ACE may have the same shape as the via TGV into which the anode connection electrode ACE is inserted. For example, in a plan view, the first connection electrode E1 may have a circular shape, and the second connection electrode E2 may have a quadrilateral shape.

The interlayer connection electrode 70 may penetrate the interlayer insulating layer IL to be connected to the anode connection electrode ACE. The interlayer connection electrode 70 may include vertical extension electrodes 81 and 82 and a horizontal extension electrode 90 that are alternately arranged along a thickness direction (e.g., the third direction DR3 or a reverse direction of the third direction DR3 (hereinafter, referred to as a third reverse direction)) of the second substrate SUB2. For example, the interlayer connection electrode 70 may include a first vertical extension electrode 81, the horizontal extension electrode 90, and a second vertical extension electrode 82 that are alternately arranged along the third reverse direction on the bottom surface 22 of the second substrate SUB2. However, the present disclosure is not limited thereto, and the interlayer connection electrode 70 may include the first vertical extension electrode 81, a first horizontal extension electrode, the second vertical extension electrode 82, a second horizontal extension electrode, and a third vertical extension electrode that are alternately arranged along the third reverse direction. The second horizontal extension electrode may be located between the second vertical extension electrode 82 and the third vertical extension electrode.

The first vertical extension electrode 81 may penetrate the first interlayer insulating layer IL1 to be connected to the anode connection electrode ACE. The first vertical extension electrode 81 may be connected to the other side of the anode connection electrode ACE. The first vertical extension electrode 81 may extend in a vertical direction (e.g., the third direction DR3).

The horizontal extension electrode 90 may penetrate the second interlayer insulating layer IL2 to be connected to the first vertical extension electrode 81. The horizontal extension electrode 90 may extend in a horizontal direction (e.g., a direction vertically intersecting the third direction DR3). For example, the horizontal extension electrode 90 may horizontally extend toward the center (e.g., the central anode connection electrode or the central via TGV0) of the second substrate SUB2. The horizontal extension electrodes 90 respectively connected to different anode connection electrodes ACE may have different lengths. For example, the horizontal extension electrodes 90 arranged on the same layer may have smaller lengths as they are closer to the center (e.g., the central anode connection electrode or the central via TGV0) of the second substrate SUB2. In other words, the horizontal extension electrodes 90 arranged in the same interlayer insulating layer IL (e.g., the second interlayer insulating layer IL2) may have larger lengths as they are closer to the edge of the second substrate SUB2.

The second vertical extension electrode 82 may penetrate the third interlayer insulating layer IL3 to be connected to the horizontal extension electrode 90. The second vertical extension electrode 82 may extend in the vertical direction (e.g., the third direction DR3). The vertical extension electrodes (e.g., 81 and 82) arranged on different layers may be located closer to the center (e.g., the central anode connection electrode ACE or the central via TGV0) of the second substrate SUB2 in a plan view as they are located farther from the bottom surface of the second substrate SUB2. For example, in a plan view, the second vertical extension electrode 82 may be located closer to the center (e.g., the central anode connection electrode ACE or the central via TGV0) of the second substrate SUB2 than the first vertical extension electrode 81.

The second vertical extension electrodes 82 may be respectively connected to the plurality of terminals TM of the driving module M1. Accordingly, the anode electrodes AE of the display module M2 may be respectively connected to the pixel transistors PTR of the driving module M1. Therefore, the driving currents Id generated by the pixel transistors PTR of the driving module M1 may be respectively provided to the anode electrodes AE of the display module M2.

According to some embodiments, the pixel circuit PC and the light emitting element ED may be located on different substrates SUB1 and SUB2. Therefore, because the anode electrode AE of the light emitting element ED is located on the second substrate SUB2, which is a glass substrate, the anode electrode AE may include a material containing silver (Ag) with high reflectivity instead of aluminum. For example, the anode electrode AE may have a triple-film structure of ITO/Ag/ITO. Accordingly, the reflectivity of the anode electrode AE may increase, thereby relatively improving light efficiency.

In addition, according to some embodiments, because the pixel defining film PDL is located on the second substrate SUB2, which is a glass substrate, the pixel defining film PDL may include a material containing an organic material. Accordingly, the taper angle of the pixel defining film PDL may be relatively reduced. As a result, the step coverage of the cathode electrode CE located on the pixel defining film PDL may be relatively improved, thereby relatively reducing the resistance of the cathode electrode CE.

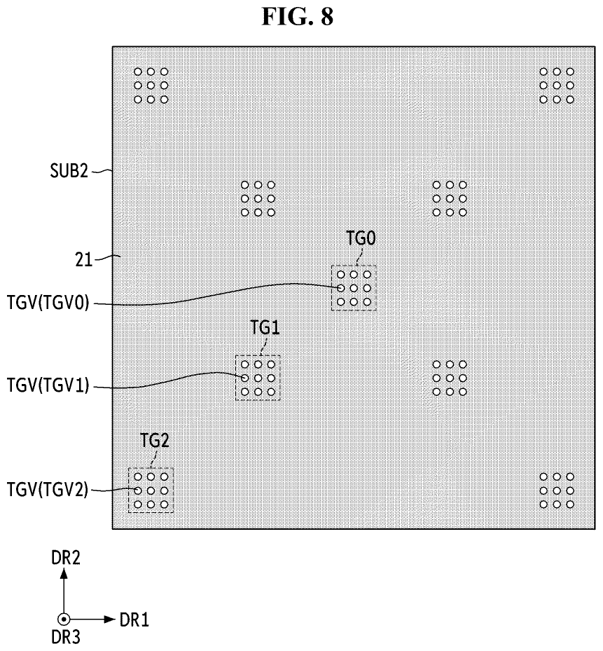

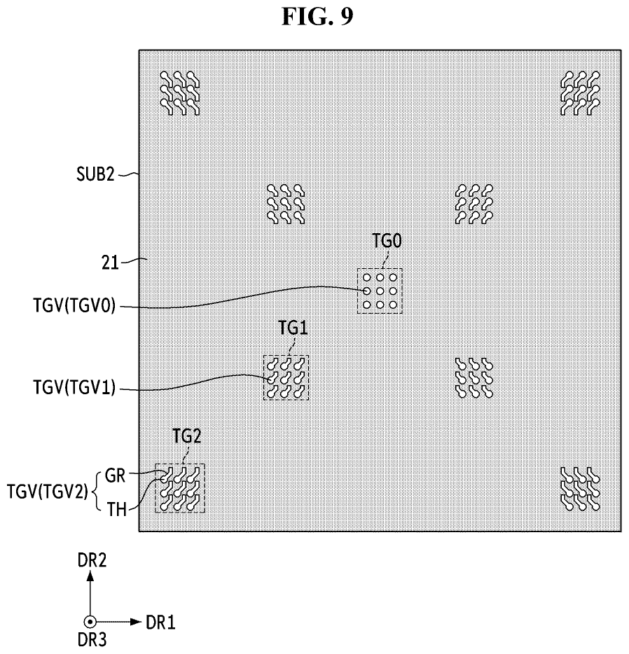

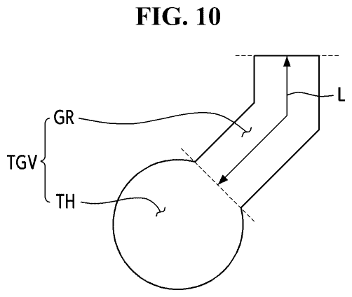

FIG. 8 is a plan view of the second substrate SUB2 according to some embodiments. FIG. 9 is a rear view of FIG. 8. FIG. 10 is an enlarged view of any one of the vias TGV of FIG. 9.

As shown in FIGS. 8 and 9, the vias TGV may be defined as a plurality of via groups. For example, the plurality of vias TGV may be classified into a central via group TG0, a first via group TG1, and a second via group TG2 based on their distances from the center of the second substrate SUB2. However, the present disclosure is not limited thereto, and there may be three or more via groups.

The central via group TG0 may include the plurality of central vias TGV0. The plurality of central vias TGV0 of the central via group TG0 may be located at the center of the second substrate SUB2. Each of the plurality of central vias TGV0 may correspond to the aforementioned central via TGV0.

The first via group TG1 may include the plurality of first vias TGV1. The plurality of first vias TGV1 of the first via group TG1 may be located between the central vias TGV0 of the central via group TG0 and the second vias TGV2 of the second via group TG2. Each of the plurality of first vias TGV1 may correspond to the aforementioned first via TGV1.

The second via group TG2 may include the plurality of second vias TGV2. Each of the plurality of second vias TGV2 may correspond to the aforementioned second via TGV2. The plurality of second vias TGV2 of the second via group TG2 may be located at the edge of the second substrate SUB2.

The length of the groove GR of the first via TGV1 included in the first via group TG1 may be greater than the length of the groove GR of the central via TGV0 included in the central via group TG0 and smaller than the length of the groove GR of the second via TGV2 included in the second via group TG2.

As shown in FIG. 10, the via TGV may include the hole TH and the groove GR. According to some embodiments, in a plan view, the groove GR may have a bent shape. A length L of the bent groove GR may be defined as a distance from one end to the other end of the groove GR. According to some embodiments, in a plan view, the anode connection electrode ACE may have the same shape as the via TGV into which the anode connection electrode ACE is inserted. For example, in a plan view, the second connection electrode E2 of the anode connection electrode ACE located in the groove GR of the via TGV of FIG. 10 may have a bent shape.

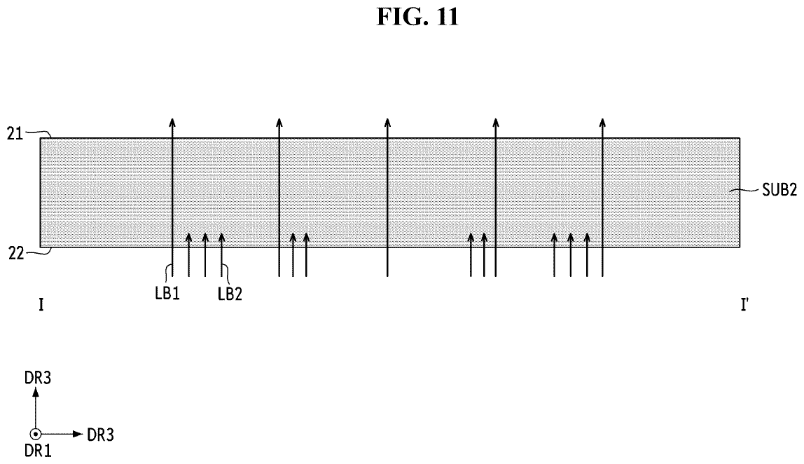

FIGS. 11, 12, 13, 14, 15, 16, 17, 18, 19, 20, and 21 are process cross-sectional views illustrating a method for fabricating the display device 10 according to some embodiments.

First, as shown in FIG. 11, laser beams LB1 and LB2 may be irradiated onto the second substrate SUB2 as a preparation step for forming the vias TGV in the second substrate SUB2. For example, a first laser beam LB1 may be irradiated onto the bottom surface 22 of the second substrate SUB2 corresponding to the hole TH of the via TGV, and a second laser beam LB2 may be irradiated onto the bottom surface 22 of the second substrate SUB2 corresponding to the groove GR of the via TGV.

The first laser beam LB1 may be irradiated onto the bottom surface 22 of the second substrate SUB2 so as to completely penetrate the second substrate SUB2, and the second laser beam LB2 may be irradiated onto the bottom surface 22 of the second substrate SUB2 so as not to penetrate the second substrate SUB2.

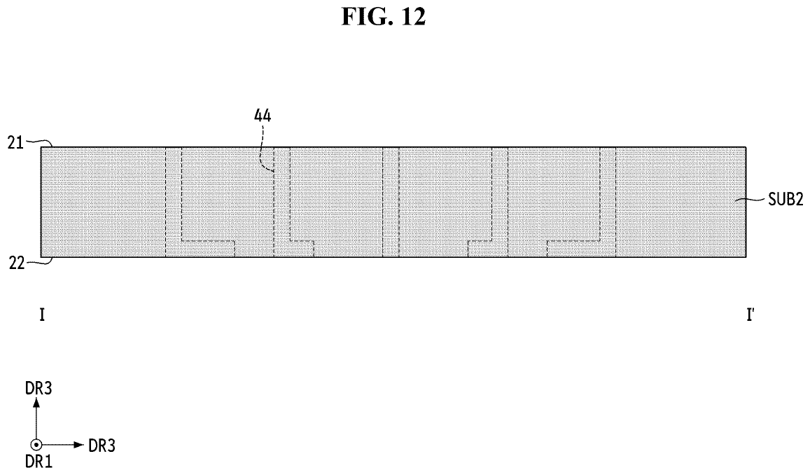

By the irradiation of the first laser beam LB1 and the second laser beam LB2 as described above, as shown in FIG. 12, a molten portion 44 having the shape of the vias TGV may be formed in the second substrate SUB2.

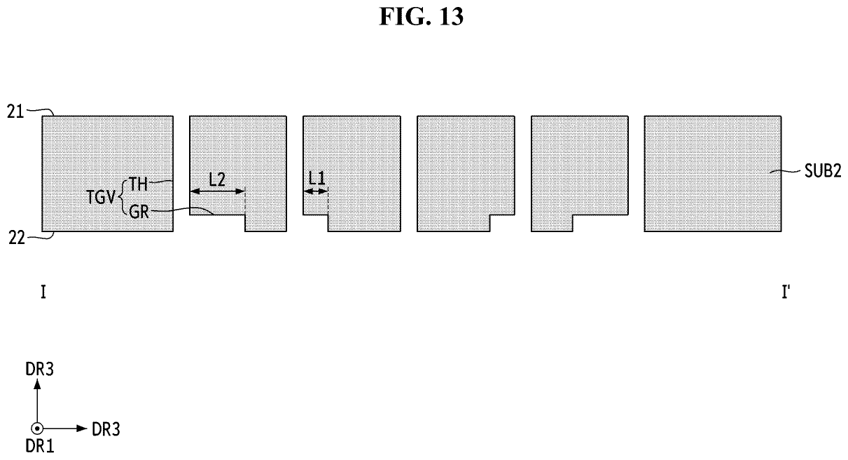

Subsequently, the second substrate SUB2 irradiated with the first and second laser beams LB1 and LB2 may be etched. By this etching process, the vias TGV may be formed in the second substrate SUB2, as shown in FIG. 13. For example, the second substrate SUB2 may be etched more in a region irradiated with the first laser beam LB1 than in a region irradiated with the second laser beam LB2, and due to this difference in etching rate, the hole TH and the groove GR having different depths may be formed.

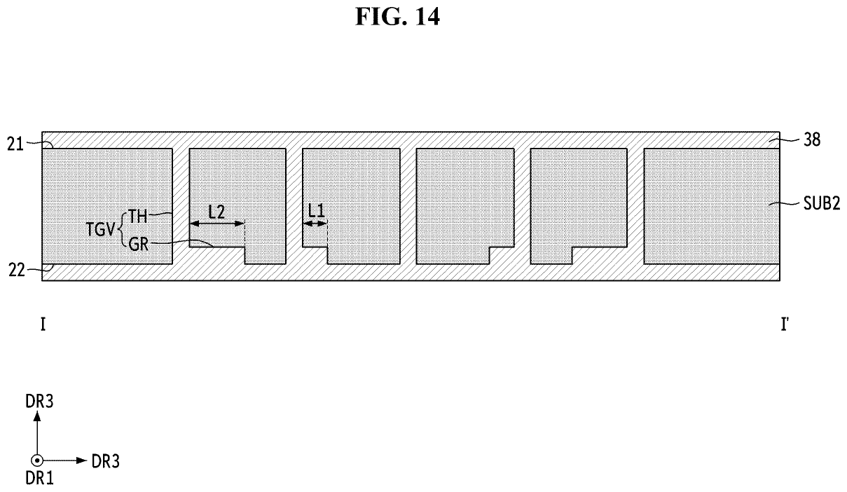

Next, as shown in FIG. 14, a metal layer 38 may be formed on the second substrate SUB2 in which the plurality of vias TGV are formed. The metal layer 38 may be formed on the second substrate SUB2 by an electroplating method. In this case, the metal layer 38 may be formed inside the vias TGV of the second substrate SUB2, on the top surface 21 of the second substrate SUB2, and on the bottom surface 22 of the second substrate SUB2.

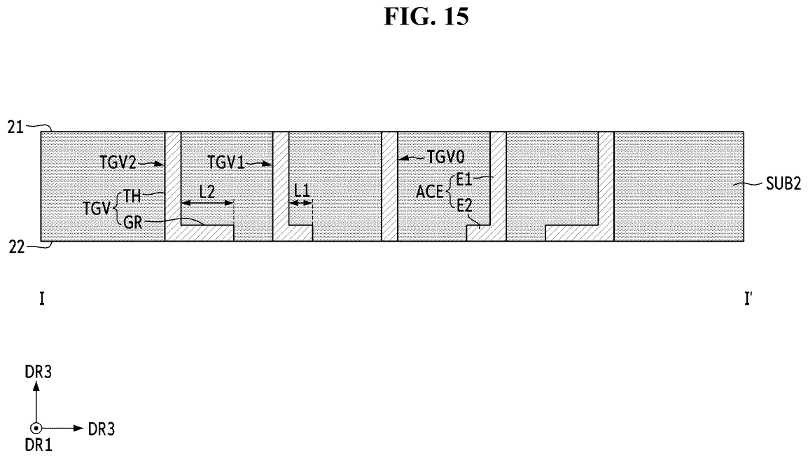

Thereafter, as shown in FIG. 15, the metal layer 38 formed on the top surface 21 of the second substrate SUB2 and the bottom surface 22 of the second substrate SUB2 may be removed, thereby forming the anode connection electrodes ACE in the vias TGV of the second substrate SUB2. Here, the metal layer 38 on the top surface 21 of the second substrate SUB2 and the bottom surface 22 of the second substrate SUB2 may be removed through chemical mechanical polishing (CMP).

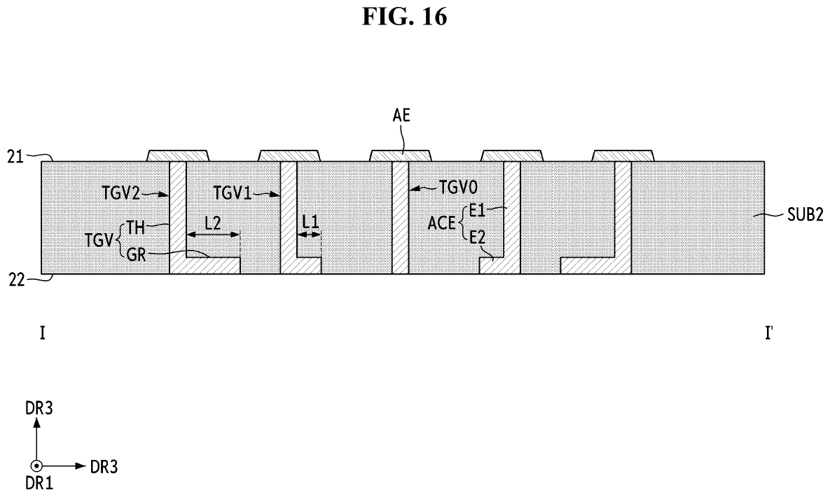

Next, as shown in FIG. 16, the anode electrodes AE may be formed on the top surface 21 of the second substrate SUB2. The anode electrodes AE may be respectively connected to the anode connection electrodes ACE in the vias TGV.

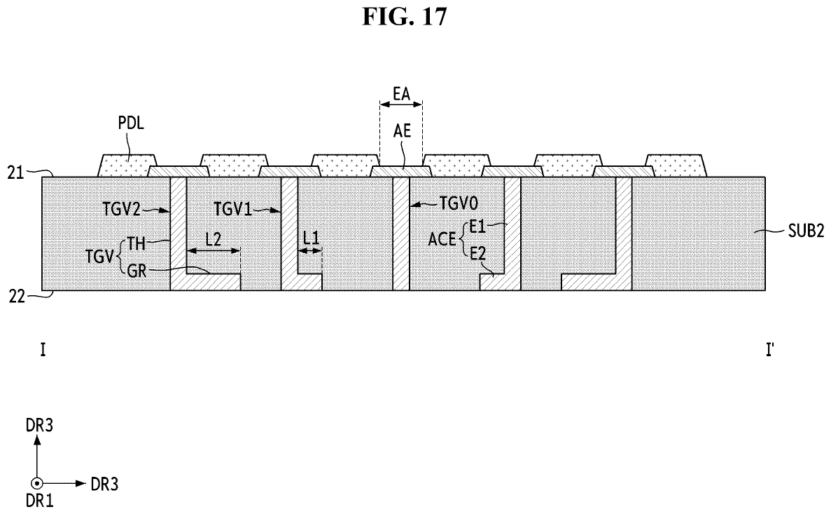

Next, as shown in FIG. 17, the pixel defining film PDL may be formed on the top surface 21 of the second substrate SUB2 so as to cover the edges of the anode electrodes AE. The pixel defining film PDL may contain an organic material.

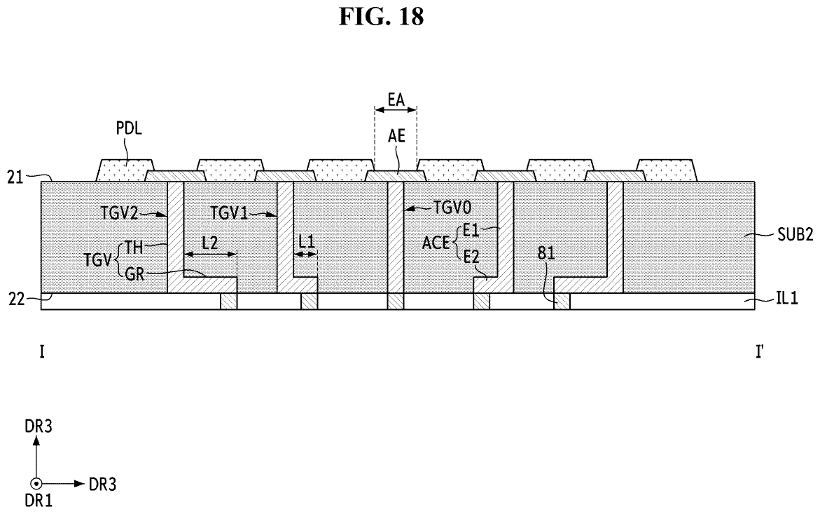

Next, as shown in FIG. 18, after the first interlayer insulating layer IL1 is formed on the bottom surface 22 of the second substrate SUB2, contact holes penetrating the first interlayer insulating layer IL1 to expose the anode connection electrodes ACE may be formed, and the first vertical extension electrodes 81 may be respectively formed in the contact holes of the first interlayer insulating layer IL1.

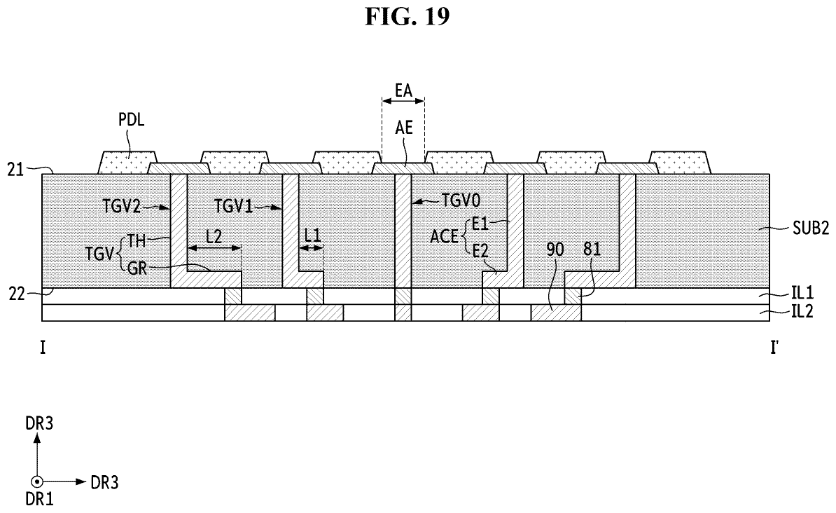

Then, as shown in FIG. 19, after the second interlayer insulating layer IL2 is formed on the first interlayer insulating layer IL1, contact holes penetrating the second interlayer insulating layer IL2 to expose the first vertical extension electrodes 81 may be formed, and the horizontal extension electrodes 90 may be respectively formed in the contact holes of the second interlayer insulating layer IL2.

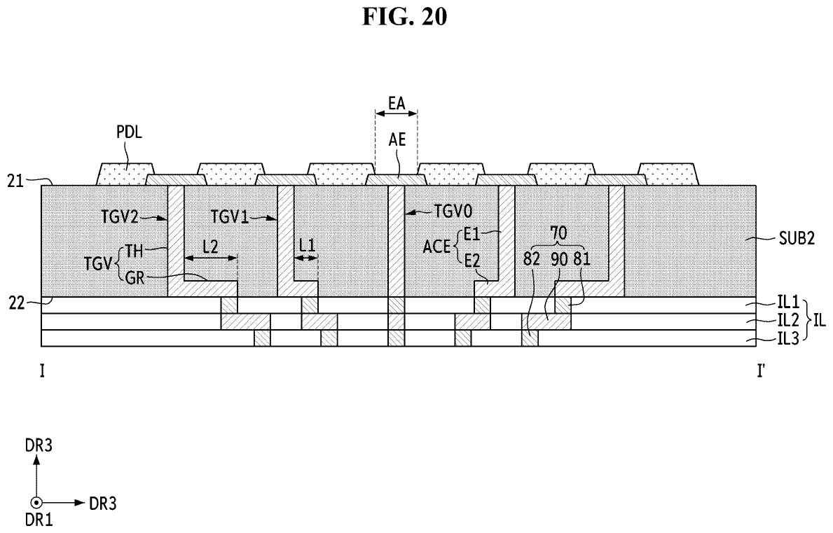

Next, as shown in FIG. 20, after the third interlayer insulating layer IL3 is formed on the second interlayer insulating layer IL2, contact holes penetrating the third interlayer insulating layer IL3 to expose the horizontal extension electrodes 90 may be formed, and the second vertical extension electrodes 82 may be respectively formed in the contact holes of the third interlayer insulating layer IL3.

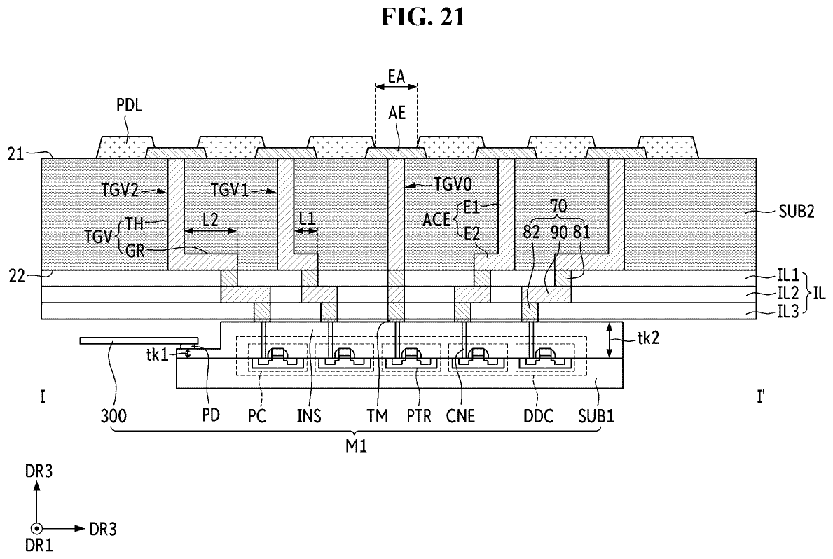

Thereafter, as shown in FIG. 21, the driving module M1 may be connected to the display module M2. For example, the terminals TM of the driving module M1 may be respectively connected to the second vertical extension electrodes 82 of the display module M2 (e.g., pads of the display module M2).

Next, as shown in FIG. 7, the light emitting layer LE may be formed on the anode electrodes AE and the pixel defining film PDL, the cathode electrode CE may be formed on the light emitting layer LE, the encapsulation layer ENC may be formed on the cathode electrode CE, and the color filter layer CFL may be formed on the encapsulation layer ENC.

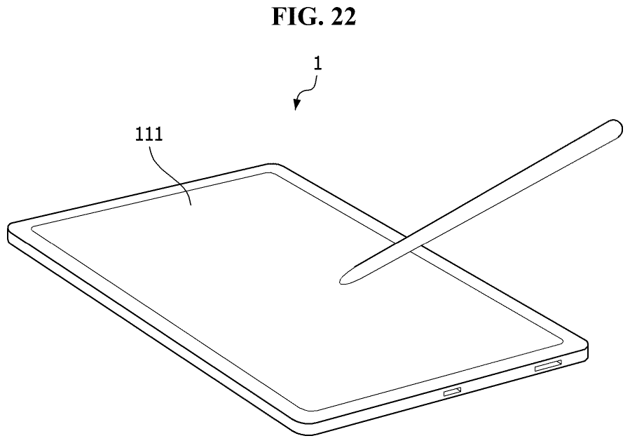

FIG. 22 is a perspective view showing an electronic device to which the display device 10 according to some embodiments is applied.

Referring to FIG. 22, a tablet 1, to which a display device 111 according to some embodiments is applied, is illustrated as an example of an electronic device. However, the display device 111 according to some embodiments is applicable not only to the tablet 1 but also to other electronic devices. For example, the display device 111 according to some embodiments may be applied to an electronic device that displays a moving image or a still image. For example, the display device 10 according to some embodiments is applicable to portable electronic devices such as a mobile phone, a smartphone, a smartwatch, a watch phone, a mobile communication terminal, an electronic notebook, an electronic book, a portable multimedia player (PMP), a navigation device, and an ultra mobile PC (UMPC). Alternatively, the display device 111 according to some embodiments may be used as a display screen of various electronic devices such as a television, a laptop computer, a monitor, a billboard, or an Internet-of-Things (IOT) device.

For example, the display device 111 of FIG. 22 may be the same as the aforementioned display device 10 of FIGS. 1 to 21.

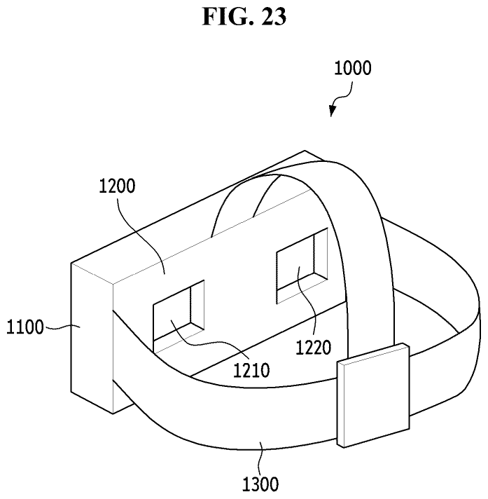

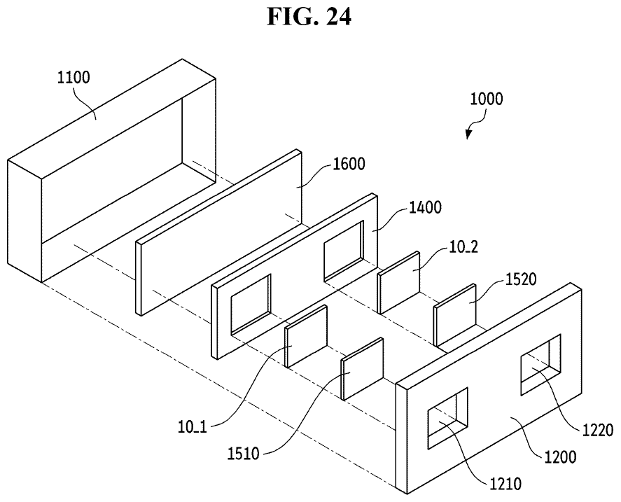

FIG. 23 is a perspective view illustrating a head mounted display according to some embodiments. FIG. 24 is an exploded perspective view illustrating an example of the head mounted display of FIG. 23. For example, FIGS. 23 and 24 show a head mounted display as an example of an optical device.

Referring to FIGS. 23 and 24, a head mounted display 1000 according to some embodiments includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. Because each of the first display device 10_1 and the second display device 10_2 is substantially the same as the display device 10 described in conjunction with FIGS. 1 to 23, the description of the first display device 10_1 and the second display device 10_2 will be omitted.

The first optical member 1510 may be located between the first display device 10_1 and the first eyepiece 1210. The second optical member 1520 may be located between the second display device 10_2 and the second eyepiece 1220. Each of the first optical member 1510 and the second optical member 1520 may include at least one convex lens.

The middle frame 1400 may be located between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be located between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. Alternatively, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is located to cover one open surface of the display device housing 1100. The housing cover 1200 may include the first eyepiece 1210 at which the user's left eye is located and the second eyepiece 1220 at which the user's right eye is located. FIGS. 23 and 24 illustrate that the first eyepiece 1210 and the second eyepiece 1220 are located separately, but the embodiments of the present disclosure are not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

The head mounted band 1300 serves to secure the display device housing 1100 to the user's head such that the first eyepiece 1210 and the second eyepiece 1220 of the housing cover 1200 remain located on the user's left and right eyes, respectively.

In addition, the head mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

The first display device 10_1 and the second display device 10_2 of FIGS. 23 and 24 may be, for example, the same as the display device 10 of FIGS. 1 to 21 described above.

The display device according to some embodiments can be applied to various electronic devices. The electronic device according to some embodiments includes the display device described above and may further include modules or devices having additional functions in addition to the display device.

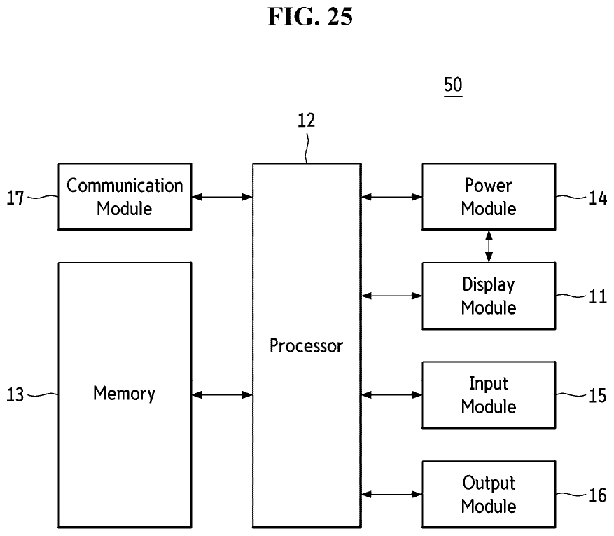

FIG. 25 is a block diagram of an electronic device according to some embodiments. Referring to FIG. 25, the electronic device 50 according to some embodiments may include a display module, a processor 12, a memory 13, and a power module 14. The electronic device 50 may further include an input module 15, a non-image output module 15 and/or a communication module 16.

The electronic device 50 may output various information in the form of images through the display module 11. When the processor 12 executes an application stored in the memory 13, image information provided by the application may be provided to the user through the display module 11. The power module 14 may include a power supply module such as a power adapter or a battery device, and a power conversion module that converts the power supplied by the power supply module to generate power required for the operation of the electronic device 50. The input module 15 may provide input information to the processor 12 and/or the display module 11. The non-image output module 15 may receive information other than images transmitted from the processor 12, such as sound, haptics, and light, and provide the information to the user. The communication module 16 is a module that is responsible for transmitting and receiving information between the electronic device 50 and an external device, and may include a receiving unit and a transmitting unit.

At least one of the components of the electronic device 50 described above may be included in the display device according to the embodiments described above. In addition, some of the individual modules functionally included in one module may be included in the display device, and others may be provided separately from the display device. For example, the display device includes a display module 11, and the processor 12, memory 13, and power module 14 may be provided in the form of other devices within the electronic device 50 other than the display device.

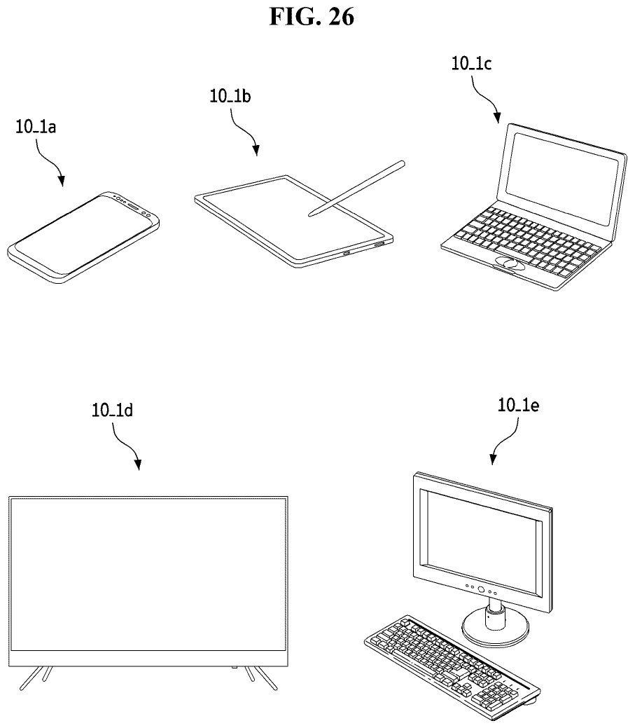

FIGS. 26, 27, and 28 are schematic diagrams of electronic devices according to various embodiments. FIGS. 26 to 28 illustrate examples of various electronic devices to which the display device according to the embodiments is applied.

FIG. 26 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also include display modules and input modules similar to smartphones 10_1, and may additionally include communication modules in some cases.

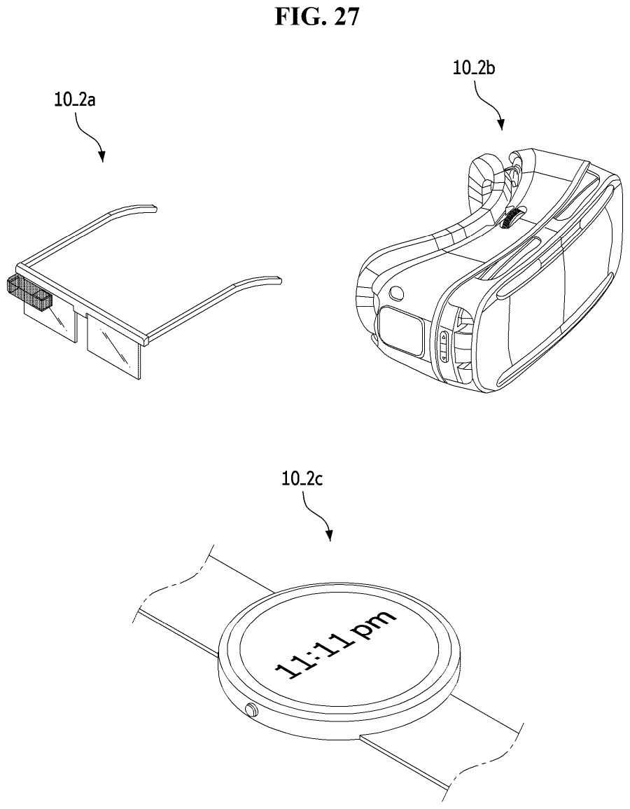

FIG. 27 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user.

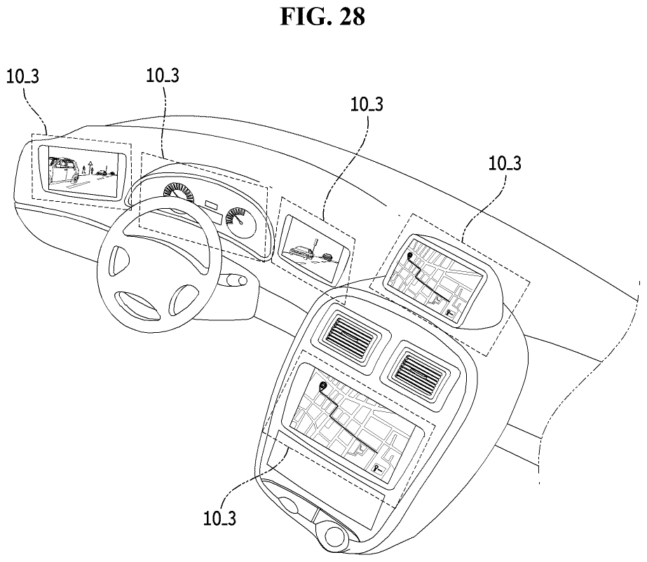

The smart watch 10_2c includes a biometric sensor as an input device, and may provide biometric information recognized by the biometric sensor to the user through the display module. FIG. 28 illustrates a case where an electronic device including a display module is applied to a vehicle. For example, the electronic device 10_3 may be applied to a dashboard, center fascia, etc. of a vehicle, or may be applied to a CID (Center Information Display) placed on a dashboard of a vehicle, or a room mirror display replacing a side mirror.

In concluding the detailed description, those skilled in the art will appreciate that many variations and modifications can be made to the disclosed embodiments without substantially departing from the spirit and scope of embodiments according to the present invention. Therefore, the disclosed embodiments of the invention are used in a generic and descriptive sense only and not for purposes of limitation.

What is claimed is:

1. A display device comprising:
a driving module comprising a first substrate and a plurality of pixel circuits on the first substrate; and
a display module on the driving module,
wherein the display module comprises:
a second substrate;
a plurality of light emitting elements on a first surface of the second substrate and respectively connected to the plurality of pixel circuits;
a plurality of vias penetrating the second substrate; and
a plurality of anode connection electrodes respectively located in the plurality of vias and respectively connecting the plurality of pixel circuits to the plurality of light emitting elements,
wherein a via from among the vias comprises a hole and a groove connected to each other,
the hole penetrates the second substrate,
the groove is on a second surface of the second substrate so as to be located between the second substrate and the driving module, and
the plurality of vias have grooves with smaller lengths as they are closer to a center of the second substrate.

2. The display device of claim 1, wherein in a plan view, the hole of the via has a circular shape, and
in the plan view, the groove of the via has a quadrilateral shape.

3. The display device of claim 1, wherein in a plan view, the hole of the via has a circular shape, and
in the plan view, the groove of the via has a bent shape.

4. The display device of claim 1, wherein a length of the groove of the via located at the center of the second substrate among the plurality of vias is zero.

5. The display device of claim 1, wherein the anode connection electrode comprises:
a first connection electrode in the hole of the via; and
a second connection electrode in the groove of the via and connected to the first connection electrode.

6. The display device of claim 5, wherein in a plan view, the first connection electrode of the anode connection electrode has a circular shape, and
In the plan view, the second connection electrode of the anode connection electrode has a quadrilateral shape.

7. The display device of claim 5, wherein in a plan view, the first connection electrode of the anode connection electrode has a circular shape, and
in the plan view, the second connection electrode of the anode connection electrode has a bent shape.

8. The display device of claim 5, wherein the plurality of anode connection electrodes have the second connection electrodes with smaller lengths as they are closer to the center of the second substrate.

9. The display device of claim 8, wherein a length of the second connection electrode of the anode connection electrode at the center of the second substrate among the plurality of anode connection electrodes is zero.

10. The display device of claim 1, wherein the light emitting element comprises:
an anode electrode on the first surface of the second substrate and connected to the anode connection electrode;
a light emitting layer on the anode electrode; and
a cathode electrode on the light emitting layer.

11. The display device of claim 10, wherein the anode electrode contains silver.

12. The display device of claim 10, wherein the display module further comprises a pixel defining film located on an edge of the anode electrode.

13. The display device of claim 12, wherein the pixel defining film contains an organic material.

14. The display device of claim 1, wherein the display module further comprises:
an interlayer insulating layer on the second surface of the second substrate; and
a plurality of interlayer connection electrodes respectively connecting the plurality of anode connection electrodes and the plurality of pixel circuits of the driving module through a plurality of contact holes of the interlayer insulating layer.

15. The display device of claim 14, wherein the interlayer connection electrodes each comprise a vertical extension electrode and a horizontal extension electrode alternately arranged between the anode connection electrode and the pixel circuit connected to each other.

16. The display device of claim 15, wherein the plurality of horizontal extension electrodes of the plurality of interlayer connection electrodes have smaller lengths as they are closer to the center of the second substrate.

17. The display device of claim 16, wherein the plurality of vertical extension electrodes of the interlayer connection electrode are closer to the center of the second substrate as they are farther from the second surface of the second substrate.

18. The display device of claim 1, wherein the first substrate is a wafer substrate, and
the second substrate is a glass substrate or a polyimide substrate.

19. The display device of claim 1, wherein the driving module comprises:
pixel transistors on the first substrate;
an insulating layer on the pixel transistors;
a plurality of pads and a plurality of terminals on the insulating layer; and
a circuit board connected to the plurality of pads,
wherein the plurality of terminals connect the plurality of pixel circuits to the plurality of anode connection electrodes, respectively, and
the insulating layer has a smaller thickness in a region overlapping the plurality of pads than in a region overlapping the plurality of terminals.

20. An electronic device comprising a display device providing a screen,
wherein the display device comprises:
a driving module comprising a first substrate and a plurality of pixel circuits on the first substrate; and
a display module on the driving module,
wherein the display module comprises:
a second substrate;
a plurality of light emitting elements on a first surface of the second substrate and respectively connected to the plurality of pixel circuits;
a plurality of vias penetrating the second substrate; and
a plurality of anode connection electrodes respectively located in the plurality of vias and respectively connecting the plurality of pixel circuits to the plurality of light emitting elements,
wherein a via from among the vias comprises a hole and a groove connected to each other,
the hole penetrates the second substrate,
the groove is on a second surface of the second substrate so as to be located between the second substrate and the driving module, and
the plurality of vias have grooves with smaller lengths as they are closer to a center of the second substrate.
